(19) United States
(12) Patent Application Publication
(10) Pub. No.: US 2017/0011989 A1
(43) Pub. Date: Jan. 12, 2017

(54) LEAD FRAME INCLUDING U-NOTCH

(71) Applicant: Infineon Technologies AG, Neubiberg (DE)

(72) Inventors: Chip King Tan, Perak (MY); Chan Lam Cha, Melaka (MY)

(73) Assignee: Infineon Technologies AG, Neubiberg (MY)

(21) Appl. No.: 14/792,908

(22) Filed: Jul. 7, 2015

(51) Int. Cl. H01L 23/495; H01L 21/48; H01L 21/56; H01L 23/00; H01L 23/31

(52) U.S. Cl. CPC H01L 23/49541; H01L 24/48; H01L 23/49503; H01L 23/3114; H01L 21/56; H01L 24/85; H01L 21/4842; H01L 21/4828; H01L 2224/48247

(57) ABSTRACT

A lead frame includes a die paddle, a first lead, and a U-notch coupling the die paddle to the first lead. The U-notch extends from the die paddle and the first lead. The U-notch is configured to be removed to electrically isolate the first lead from the die paddle.

### BACKGROUND

Semiconductor devices may include a semiconductor chip coupled to a lead frame to provide a semiconductor device package. Example semiconductor device packages include Quad Flat Packages (QFPs), Shrink, Small-Outline Packages (SSOPs), and Very thin Quad Flat Non-leaded packages (VQFNs). A dual row lead frame includes two rows of leads including an inner row of leads adjacent to a die paddle and an outer row of leads, where the inner row of leads is between the outer row of leads and the die paddle. For a dual row QFP, SSOP, VQFN, or other dual row semiconductor device package, at some point during the fabrication process, each of the inner leads and each of the outer leads are separated from each other to provide individual contact elements.

For these and other reasons, there is a need for the present invention.

### SUMMARY

One example of a lead frame includes a die paddle, a first lead, and a U-notch coupling the die paddle to the first lead. The U-notch extends from the die paddle and the first lead. The U-notch is configured to be removed to electrically isolate the first lead from the die paddle.

### BRIEF DESCRIPTION OF THE DRAWINGS

FIG. 1A illustrates a top view and FIG. 1B illustrates a cross-sectional view of one example of a lead frame.

FIG. 2 illustrates a cross-sectional view of one example of a lead frame.

FIG. 3 illustrates a cross-sectional view of one example of a semiconductor device assembly after die bonding.

FIG. 4 illustrates a cross-sectional view of one example of a semiconductor device assembly after wire bonding.

FIG. 5 illustrates a cross-sectional view of one example of a semiconductor device assembly after encapsulation.

FIG. 6 illustrates a cross-sectional view of one example of a semiconductor device assembly after removing the U-notch.

FIG. 7 illustrates a cross-sectional view of one example of a semiconductor device package after lead forming.

FIG. 8 is a flow diagram illustrating one example of a method for fabricating a semiconductor device.

### DETAILED DESCRIPTION

In the following detailed description, reference is made to the accompanying drawings which form a part hereof, and in which is shown by way of illustration specific examples in which the disclosure may be practiced. It is to be understood that other examples may be utilized and structural changes may be made without departing from the scope of the present disclosure. The following detailed description, therefore, is not to be taken in a limiting sense, and the scope of the present disclosure is defined by the appended claims. It is to be understood that features of the various examples described herein may be combined, in part or whole, with each other, unless specifically noted otherwise.

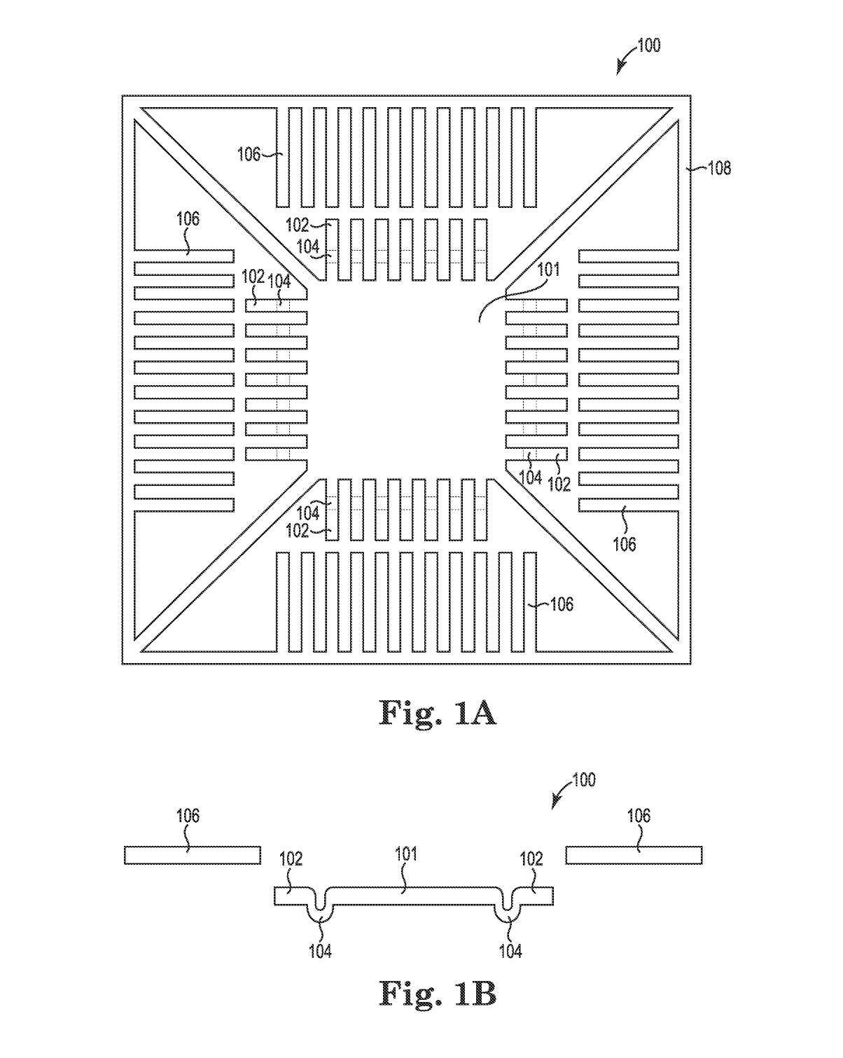

FIG. 1A illustrates a top view and FIG. 1B illustrates a cross-sectional view of one example of a lead frame 100. Lead frame 100 may be used to fabricate a dual row QFP, SSOP, VQFN, or other suitable dual row semiconductor device package. Lead frame 100 is made of copper or another suitable metal and may be plated (e.g., with silver, nickel, or gold). Lead frame 100 includes a die paddle 101, a plurality of first leads 102 (i.e., inner leads), a plurality of U-notches 104, a plurality of second leads 106 (i.e., outer leads), and a support structure 108. Each first lead 102 is coupled to die paddle 101 via a respective U-notch 104.

As illustrated in FIG. 1B, each U-notch 104 extends from die paddle 101 and a respective first lead 102 in a direction perpendicular to the die paddle (i.e., below die paddle 101 and first lead 102). Each U-notch 104 is configured to be removed during the fabrication of a semiconductor device package to electrically isolate each first lead 102 from die paddle 101. While each U-notch 104 is illustrated as having a U-shape defined by rounded edges, in other examples each U-notch 104 may have a U-shape defined by straight edges with corners between the straight edges. In other examples, each U-notch 104 may have another suitable shape that extends from die paddle 101 and a respective first lead 102, and that once removed electrically isolates die paddle 101 from the respective first lead 102. For example, each U-notch 104 may have a V-shape.

Each second lead 106 is coupled to support structure 108 such that first leads 102 are between second leads 106 and die paddle 101. Second leads 106 are spaced apart from first leads 102 in a direction parallel to die paddle 101 (i.e., in the lateral direction). As illustrated in FIG. 1B, in one example second leads 106 are also spaced apart from first leads 106 in a direction perpendicular to the die paddle (i.e., in the vertical direction). Lead frame 100 may include first leads 102 and second leads 106 on four sides of die paddle 101, as illustrated in FIG. 1A, or may include first leads 102 and second leads 106 on only two opposite sides of die paddle 101. Lead frame 100 may include any suitable number of first leads 102 and second leads 106 on each side of die paddle 101. First leads 102 may be aligned with second leads 106 as illustrated in FIGS. 1A and 1B or first leads 102 may be offset with respect to second leads 106.

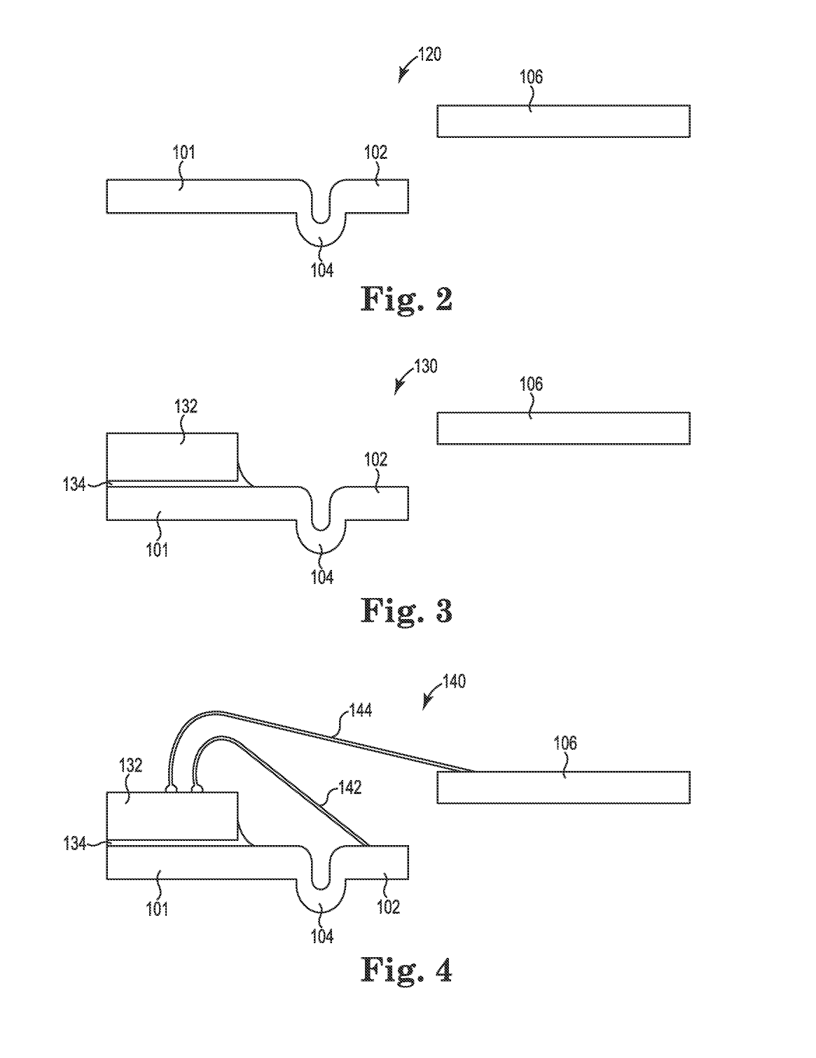

The following FIGS. 2-7 illustrate one example of fabricating a semiconductor device package using a dual row lead frame, such as dual row lead frame 100 previously described and illustrated with reference to FIGS. 1A and 1B.

FIG. 2 illustrates a cross-sectional view of one example of a lead frame 120. FIG. 2 illustrates one-half of lead frame 120 for simplicity. The other half of lead frame 120 is similar to the half illustrated. Lead frame 120 includes a die paddle 101, a first lead 102, a U-notch 104, and a second lead 106. While FIG. 2 illustrates a cross-sectional view including one first lead 102, one U-notch 104, and one second lead 106, lead frame 120 may include any suitable number of first leads 102, respective U-notches 102, and second leads 106 supported by a support structure (not shown). Accordingly, while the following description with reference to FIGS. 2-7 refers to one first lead 102, one U-notch 104, and one second lead 106, the description is applicable to devices including any suitable number of first leads, U-notches, and second leads.

First lead 102 is coupled to die paddle 101 via U-notch 104. U-notch 104 extends from die paddle 101 and first lead 102 in a direction perpendicular to the die paddle (i.e., below die paddle 101 and first lead 102). U-notch 104 is configured to be removed during the fabrication of a semiconductor device package to electrically isolate first lead 102 from die paddle 101. Second lead 106 is spaced apart from first lead 102 in a direction parallel to die paddle 101 (i.e., in the lateral direction) and in a direction perpendicular to the die paddle (i.e., in the vertical direction).

FIG. 3 illustrates a cross-sectional view of one example of a semiconductor device assembly 130 after die bonding. A semiconductor chip 132 is coupled to die paddle 101 via a joint 134. Joint 134 may be a diffusion solder joint, a soft solder joint, a sintered joint, an adhesive material, or other suitable material for coupling semiconductor chip 132 to die paddle 101. In one example, joint 134 electrically couples semiconductor chip 132 to die paddle 101. In another example, joint 134 thermally couples semiconductor chip 132 to die paddle 101, and die paddle 101 provides a heat sink for semiconductor chip 132.

FIG. 4 illustrates a cross-sectional view of one example of a semiconductor device assembly 140 after wire bonding. A first bond wire 142 is bonded to a first contact of semiconductor chip 132 and first lead 102 to electrically couple semiconductor chip 132 to first lead 102. A second bond wire 144 is bonded to a second contact of semiconductor chip 132 and second lead 106 to electrically couple semiconductor chip 132 to second lead 106. In other examples, semiconductor chip 132 may be electrically coupled to first lead 102 and/or second lead 106 via ribbons, clips, or other suitable interconnects.

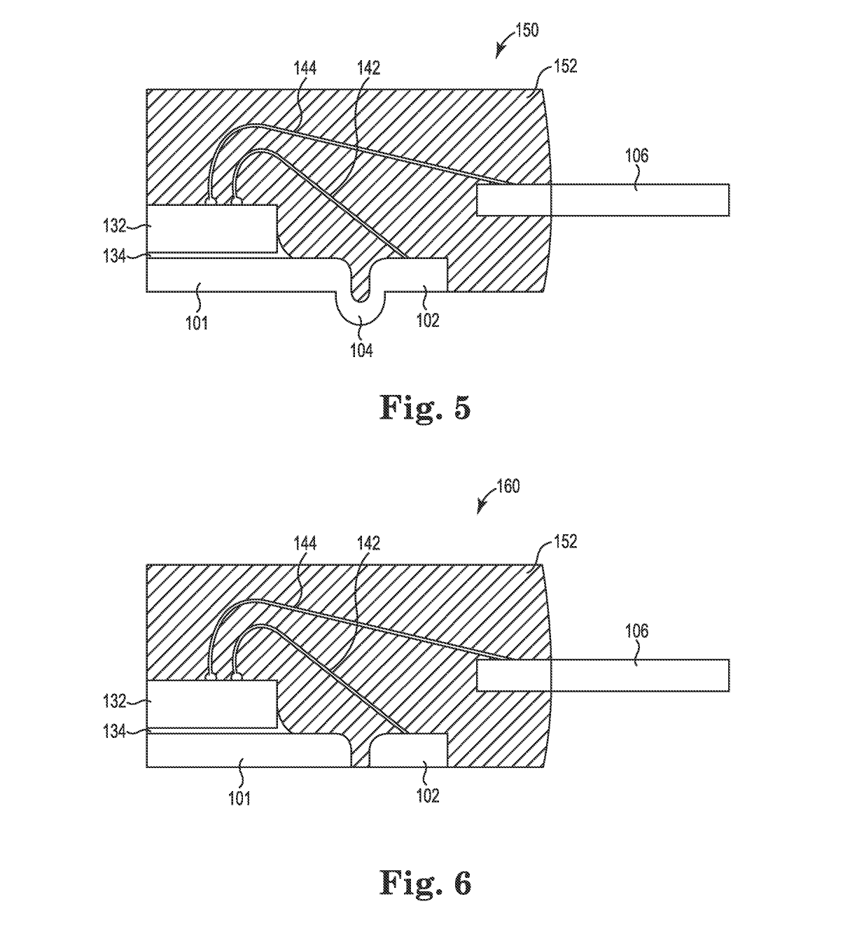

FIG. 5 illustrates a cross-sectional view of one example of a semiconductor device assembly 150 after encapsulation. Semiconductor chip 132, joint 134, bond wires 142 and 144, and portions of die paddle 101, U-notch 104, first lead 102, and second lead 106 are encapsulated with an encapsulation material 152 (e.g., mold material). After encapsulation, the bottom surface of die paddle 101, U-notch 104, and first lead 102 remains exposed. A portion of second lead 106 also remains exposed. Encapsulation material 152 fills the space above U-notch 104 between die paddle 101 and first lead 102. Die paddle 101 and second leads 106 of semiconductor device assembly 150 are then separated from each other by removing the lead frame support structure (e.g., support structure 108 of FIG. 1A) interconnecting the second leads and the die paddle.

FIG. 6 illustrates a cross-sectional view of one example of a semiconductor device assembly 160 after removing the U-notch 104. U-notch 104 is removed by grinding, mechanical sawing, chemical etching, laser cutting, or another suitable process to electrically isolate first lead 102 from die paddle 101. In one example, mold flash on the bottom of die paddle 101 and/or first lead 102 due to the encapsulation process may be simultaneously removed with the U-notch (e.g., by grinding). After the removal of U-notch 104, the space between die paddle 101 and first lead 102 remains filled with encapsulation material 152.

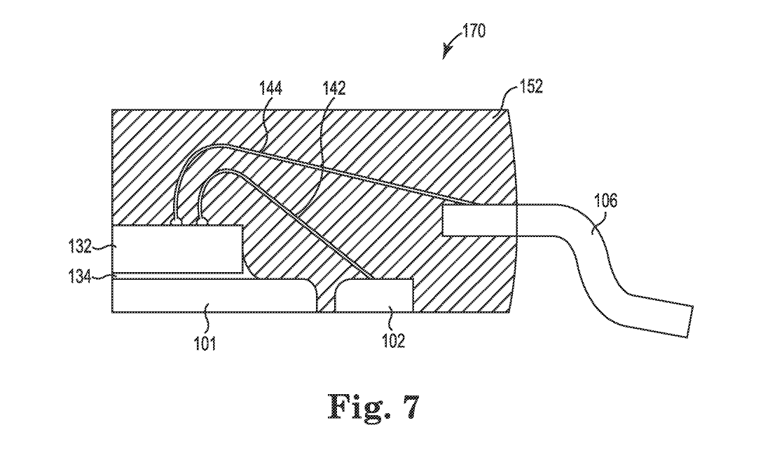

FIG. 7 illustrates a cross-sectional view of one example of a semiconductor device package 170 after lead forming. Second lead 106 is suitably shaped to provide a surface mountable semiconductor device package, such as a dual row QFP or SSOP. First lead 102 and second lead 106 provide electrical contacts to semiconductor chip 132.

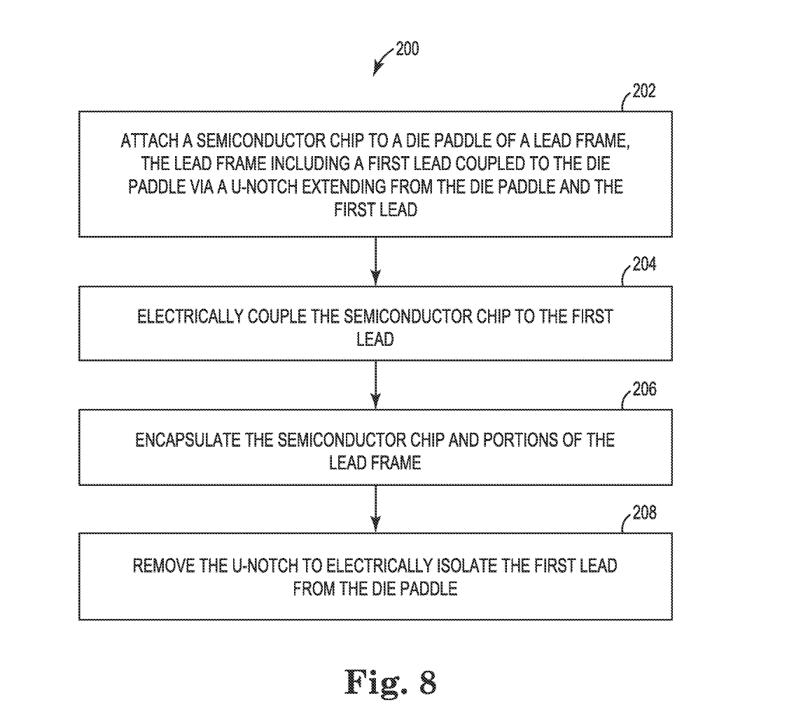

FIG. 8 is a flow diagram illustrating one example of a method 200 for fabricating a semiconductor device. At 202, a semiconductor chip is attached to a die paddle of a lead frame, where the lead frame includes a first lead coupled to the die paddle via a U-notch extending from the die paddle and the first lead. At 204, the semiconductor chip is electrically coupled to the first lead. In one example, electrically coupling the semiconductor chip to the first lead includes wire bonding the semiconductor chip to the first lead. At 206, the semiconductor chip and portions of the lead frame are encapsulated. In one example, the encapsulating includes encapsulating with a mold material. At 208, the U-notch is removed to electrically isolate the first lead from the die paddle. In one example, removing the U-notch comprises grinding the U-notch. In another example, removing the U-notch comprises mechanical sawing, chemical etching, or laser cutting the U-notch. Removing the U-notch may include simultaneously removing the U-notch and mold flash from the die paddle.

In one example, the lead frame may include a second lead spaced apart from the first lead, where the first lead is between the second lead and the die paddle. The method may further include electrically coupling the semiconductor chip to the second lead prior to the encapsulation. In another example, the lead frame may include a plurality of first leads, where each first lead is coupled to the die paddle via a U-notch extending from the die paddle and the first lead. The method may further include electrically coupling the semiconductor chip to each first lead and removing each U-notch to electrically isolate each first lead from the die paddle.

Although specific examples have been illustrated and described herein, a variety of alternate and/or equivalent implementations may be substituted for the specific examples shown and described without departing from the scope of the present disclosure. This application is intended to cover any adaptations or variations of the specific examples discussed herein. Therefore, it is intended that this disclosure be limited only by the claims and the equivalents thereof.

1. A lead frame comprising:
a die paddle;
a first lead; and
a U-notch coupling the die paddle to the first lead, the U-notch extending from the die paddle and the first lead.

2. The lead frame of claim 1, wherein the U-notch is configured to be removed to electrically isolate the first lead from the die paddle.

3. The lead frame of claim 1, further comprising:
a second lead spaced apart from the first lead,
wherein the first lead is between the die paddle and the second lead.

4. The lead frame of claim 3, wherein the second lead is spaced apart from the first lead in a direction perpendicular to the die paddle.

5. The lead frame of claim 3, further comprising:
a plurality of first leads, each first lead coupled to the die paddle via a U-notch extending from the die paddle and the first lead; and
a plurality of second leads spaced apart from the first leads,
wherein the first leads are between the die paddle and the second leads.

6. The lead frame of claim 5, wherein the plurality of first leads comprises first leads coupled to a first side of the die paddle and first leads coupled to a second side of the die paddle opposite to the first side.

7. The lead frame of claim 6, wherein the plurality of first leads comprises first leads coupled to a third side of the die paddle and first leads coupled to a fourth side of the die paddle opposite to the third side.

8. A semiconductor device assembly comprising:
a lead frame comprising a die paddle and a first lead coupled to the die paddle via a U-notch extending from the die paddle and the first lead in a direction perpendicular to the die paddle;
a semiconductor chip coupled to the die paddle; and
a first bond wire electrically coupling the semiconductor chip to the first lead.

9. The semiconductor device assembly of claim 8, wherein the U-notch is configured to be removed to electrically isolate the first lead from the die paddle.

10. The semiconductor device assembly of claim 8, wherein the lead frame comprises a second lead spaced apart from the first lead, the second lead electrically coupled to the semiconductor chip via a second bond wire, and
wherein the first lead is between the second lead and the die paddle.

11. The semiconductor device assembly of claim 10, wherein the second lead is spaced apart from the first lead in a direction parallel to the die paddle.

12. The semiconductor device assembly of claim 8, wherein the lead frame comprises a plurality of first leads, each first lead coupled to the die paddle via a U-notch extending from the die paddle and the first lead in the direction perpendicular to the die paddle,
wherein the lead frame comprises a plurality of second leads spaced apart from the first leads,
wherein the first leads are between the die paddle and the second leads, and
wherein each of the first and second leads is coupled to the semiconductor chip via a bond wire.

13. The semiconductor device assembly of claim 8, further comprising:
an encapsulation material encapsulating the semiconductor chip, the first bond wire, and portions of the lead frame.

14. A method for fabricating a semiconductor device, the method comprising:
attaching a semiconductor chip to a die paddle of a lead frame, the lead frame including a first lead coupled to the die paddle via a U-notch extending from the die paddle and the first lead;
electrically coupling the semiconductor chip to the first lead;
encapsulating the semiconductor chip and portions of the lead frame; and
removing the U-notch to electrically isolate the first lead from the die paddle.

15. The method of claim 14, wherein removing the U-notch comprises grinding the U-notch.

16. The method of claim 14, wherein removing the U-notch comprises mechanical sawing, chemical etching, or laser cutting the U-notch.

17. The method of claim 14, wherein electrically coupling the semiconductor chip to the first lead comprises wire bonding the semiconductor chip to the first lead.

18. The method of claim 14, wherein the lead frame includes a second lead spaced apart from the first lead and wherein the first lead is between the second lead and the die paddle, the method further comprising:
electrically coupling the semiconductor chip to the second lead prior to the encapsulation.

19. The method of claim 14, wherein the lead frame comprises a plurality of first leads, each first lead coupled to the die paddle via a U-notch extending from the die paddle and the first lead, the method further comprising:
electrically coupling the semiconductor chip to each first lead; and
removing each U-notch to electrically isolate each first lead from the die paddle.

20. The method of claim 14, wherein the encapsulating comprises encapsulating with a mold material, and
wherein removing the U-notch comprises simultaneously removing the U-notch and mold flash from the die paddle.
